(19) United States
(12) Patent Application Publication
(10) Pub. No.: US 2016/0173130 A1
(43) Pub. Date: Jun. 16, 2016

(54) EARLY DECODE ATTEMPT OF LOWER RATE LTE CODE BLOCKS THAT ARE REPEAT COMBINED MULTIPLE TIMES

(71) Applicant: QUALCOMM Incorporated, San Diego, CA (US)

(72) Inventors: James Leslie KRYSL, San Diego, CA (US); Michael A. KONGELF, San Diego, CA (US); Michael Lee MCCLOUD, San Diego, CA (US)

(21) Appl. No.: 14/566,432

(22) Filed: Dec. 10, 2014

(51) Int. Cl. H03M 13/11; H03M 13/00; H04L 1/00

(52) U.S. Cl. CPC H03M 13/1111; H04L 1/0057; H04L 1/005; H03M 13/611

(57) ABSTRACT

A method, an apparatus, and a computer program product for wireless communication are provided. The apparatus receives configuration information indicating a number of transmissions. The number of transmissions corresponds to a number of repetitions of a code block that will be transmitted by a base station. The apparatus receives a first number of repetitions of the code block, where the first number is less than the number of transmissions. The apparatus proceeds to decode the code block using the first number of repetitions, without waiting to successfully receive the remaining repetitions in the number of repetitions from the base station.

### BACKGROUND

1. Field

The present disclosure relates generally to communication systems, and more particularly, to an early decode attempt of lower rate LTE code blocks that are repeat combined multiple times.

2. Background

Wireless communication systems are widely deployed to provide various telecommunication services such as telephony, video, data, messaging, and broadcasts. Typical wireless communication systems may employ multiple-access technologies capable of supporting communication with multiple users by sharing available system resources (e.g., bandwidth, transmit power). Examples of such multiple-access technologies include code division multiple access (CDMA) systems, time division multiple access (TDMA) systems, frequency division multiple access (FDMA) systems, orthogonal frequency division multiple access (OFDMA) systems, single-carrier frequency division multiple access (SC-FDMA) systems, and time division synchronous code division multiple access (TD-SCDMA) systems.

These multiple access technologies have been adopted in various telecommunication standards to provide a common protocol that enables different wireless devices to communicate on a municipal, national, regional, and even global level. An example of an emerging telecommunication standard is Long Term Evolution (LTE). LTE is a set of enhancements to the Universal Mobile Telecommunications System (UMTS) mobile standard promulgated by Third Generation Partnership Project (3GPP). LTE is designed to better support mobile broadband Internet access by improving spectral efficiency, lowering costs, improving services, making use of new spectrum, and better integrating with other open standards using OFDMA on the downlink (DL), SC-FDMA on the uplink (UL), and multiple-input multiple-output (MIMO) antenna technology. However, as the demand for mobile broadband access continues to increase, there exists a need for further improvements in LTE technology. Preferably, these improvements should be applicable to other multi-access technologies and the telecommunication standards that employ these technologies.

### SUMMARY

In an aspect of the disclosure, a method, a computer program product, and an apparatus are provided. The apparatus receives configuration information indicating a number of transmissions. The number of transmissions corresponds to a number of repetitions of a code block that will be transmitted by a base station. The apparatus receives a first number of repetitions of the code block, where the first number is less than the number of transmissions. The apparatus proceeds to decode the code block using the first number of repetitions, without waiting to successfully receive the remaining repetitions in the number of repetitions from the base station.

### BRIEF DESCRIPTION OF THE DRAWINGS

FIG. 1 is a diagram illustrating an example of a network architecture.

FIG. 2 is a diagram illustrating an example of an access network.

FIG. 3 is a diagram illustrating an example of a DL frame structure in LTE.

FIG. 4 is a diagram illustrating an example of an UL frame structure in LTE.

FIG. 5 is a diagram illustrating an example of a radio protocol architecture for the user and control planes.

FIG. 6 is a block diagram of an eNB in communication with a UE in an access network.

FIG. 7 is a diagram illustrating a base station in communication with a UE.

FIG. 8 is a diagram illustrating data processing modules in a transmitter.

FIG. 9 is a diagram illustrating data processing modules in a receiver.

FIG. 10A is a diagram illustrating an exemplary encoding and transmission of a transport block by a transmitter in accordance with various aspects of the disclosure.

FIG. 10B is a diagram illustrating an exemplary reception and decoding of a code block by a receiver in accordance with various aspects of the disclosure.

FIG. 11 is a diagram illustrating log likelihood ratios (LLRs) determined for a code block received in an over-the-air (OTA) transmission.

FIG. 12A is a diagram illustrating an exemplary encoding and transmission of a transport block by a transmitter in accordance with various aspects of the disclosure.

FIG. 12B is a diagram illustrating an exemplary reception and decoding of code blocks by a receiver in accordance with various aspects of the disclosure.

FIG. 13 is a flow chart of an algorithm for decoding a code block in accordance with various aspects of the disclosure.

FIG. 14 is a flow chart of a method of wireless communication.

FIG. 15 is a conceptual data flow diagram illustrating the data flow between different modules/means/components in an exemplary apparatus.

FIG. 16 is a diagram illustrating an example of a hardware implementation for an apparatus employing a processing system.

### DETAILED DESCRIPTION

The detailed description set forth below in connection with the appended drawings is intended as a description of various configurations and is not intended to represent the configurations in which the concepts described herein may be practiced. The detailed description includes specific details for the purpose of providing a thorough understanding of various concepts. However, it will be apparent to those skilled in the art that these concepts may be practiced without these specific details. In some instances, well known structures and components are shown in block diagram form in order to avoid obscuring such concepts.

Several aspects of telecommunication systems will now be presented with reference to various apparatus and methods. These apparatus and methods will be described in the following detailed description and illustrated in the accompanying drawings by various blocks, modules, components, circuits, steps, processes, algorithms, etc. (collectively referred to as “elements”). These elements may be implemented using electronic hardware, computer software, or any combination thereof. Whether such elements are implemented as hardware or software depends upon the particular application and design constraints imposed on the overall system.

By way of example, an element, or any portion of an element, or any combination of elements may be implemented with a “processing system” that includes one or more processors. Examples of processors include microprocessors, microcontrollers, digital signal processors (DSPs), field programmable gate arrays (FPGAs), programmable logic devices (PLDs), state machines, gated logic, discrete hardware circuits, and other suitable hardware configured to perform the various functionality described throughout this disclosure. One or more processors in the processing system may execute software. Software shall be construed broadly to mean instructions, instruction sets, code, code segments, program code, programs, subprograms, software modules, applications, software applications, software packages, routines, subroutines, objects, executables, threads of execution, procedures, functions, etc., whether referred to as software, firmware, middleware, microcode, hardware description language, or otherwise.

Accordingly, in one or more exemplary embodiments, the functions described may be implemented in hardware, software, firmware, or any combination thereof. If implemented in software, the functions may be stored on or encoded as one or more instructions or code on a computer-readable medium. Computer-readable media includes computer storage media. Storage media may be any available media that can be accessed by a computer. By way of example, and not limitation, such computer-readable media can comprise a random-access memory (RAM), a read-only memory (ROM), an electrically erasable programmable ROM (EEPROM), compact disk ROM (CD-ROM) or other optical disk storage, magnetic disk storage or other magnetic storage devices, or any other medium that can be used to carry or store desired program code in the form of instructions or data structures and that can be accessed by a computer. Combinations of the above should also be included within the scope of computer-readable media.

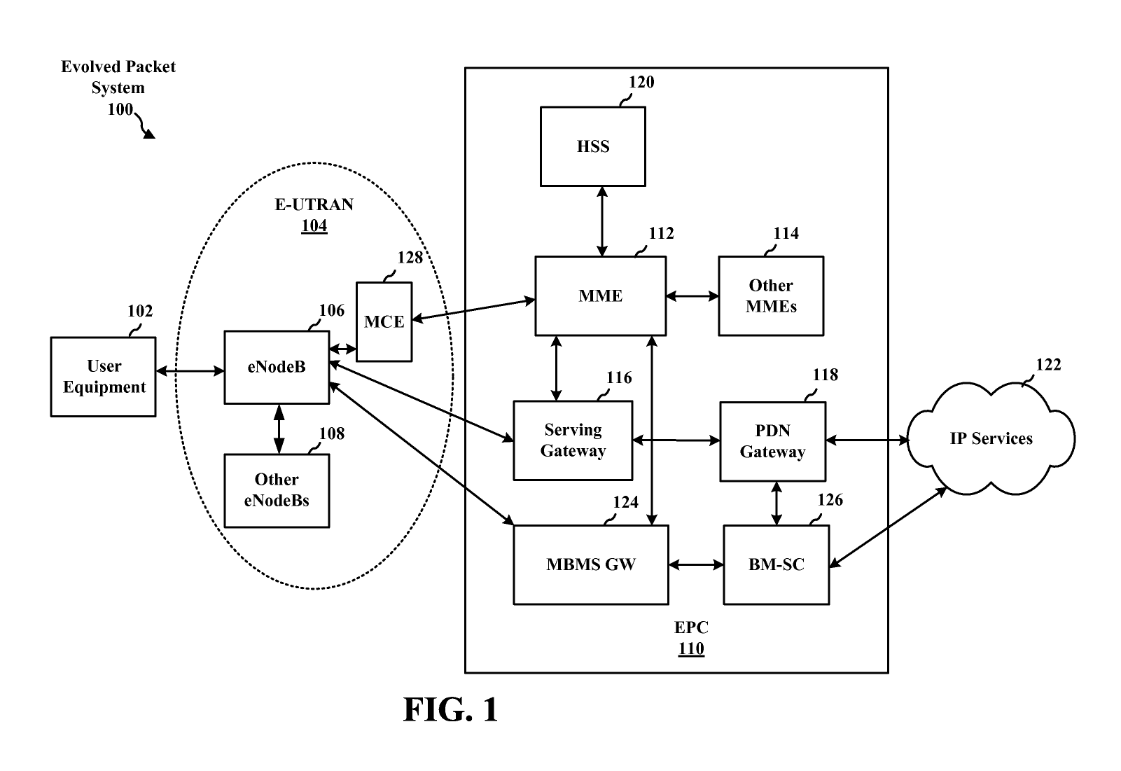

FIG. 1 is a diagram illustrating an LTE network architecture 100. The LTE network architecture 100 may be referred to as an Evolved Packet System (EPS) 100. The EPS 100 may include one or more user equipment (UE) 102, an Evolved UMTS Terrestrial Radio Access Network (E-UTRAN) 104, an Evolved Packet Core (EPC) 110, and an Operator's Internet Protocol (IP) Services 122. The EPS can interconnect with other access networks, but for simplicity those entities/interfaces are not shown. As shown, the EPS provides packet-switched services, however, as those skilled in the art will readily appreciate, the various concepts presented throughout this disclosure may be extended to networks providing circuit-switched services.

The E-UTRAN includes the evolved Node B (eNB) 106 and other eNBs 108, and may include a Multicast Coordination Entity (MCE) 128. The eNB 106 provides user and control planes protocol terminations toward the UE 102. The eNB 106 may be connected to the other eNBs 108 via a backhaul (e.g., an X2 interface). The MCE 128 allocates time/frequency radio resources for evolved Multimedia Broadcast Multicast Service (MBMS) (eMBMS), and determines the radio configuration (e.g., a modulation and coding scheme (MCS)) for the eMBMS. The MCE 128 may be a separate entity or part of the eNB 106. The eNB 106 may also be referred to as a base station, a Node B, an access point, a base transceiver station, a radio base station, a radio transceiver, a transceiver function, a basic service set (BSS), an extended service set (ESS), or some other suitable terminology. The eNB 106 provides an access point to the EPC 110 for a UE 102. Examples of UEs 102 include a cellular phone, a smart phone, a session initiation protocol (SIP) phone, a laptop, a personal digital assistant (PDA), a satellite radio, a global positioning system, a multimedia device, a video device, a digital audio player (e.g., MP3 player), a camera, a game console, a tablet, or any other similar functioning device. The UE 102 may also be referred to by those skilled in the art as a mobile station, a subscriber station, a mobile unit, a subscriber unit, a wireless unit, a remote unit, a mobile device, a wireless device, a wireless communications device, a remote device, a mobile subscriber station, an access terminal, a mobile terminal, a wireless terminal, a remote terminal, a handset, a user agent, a mobile client, a client, or some other suitable terminology.

The eNB 106 is connected to the EPC 110. The EPC 110 may include a Mobility Management Entity (MME) 112, a Home Subscriber Server (HSS) 120, other MMEs 114, a Serving Gateway 116, a Multimedia Broadcast Multicast Service (MBMS) Gateway 124, a Broadcast Multicast Service Center (BM-SC) 126, and a Packet Data Network (PDN) Gateway 118. The MME 112 is the control node that processes the signaling between the UE 102 and the EPC 110. Generally, the MME 112 provides bearer and connection management. All user IP packets are transferred through the Serving Gateway 116, which itself is connected to the PDN Gateway 118. The PDN Gateway 118 provides UE IP address allocation as well as other functions. The PDN Gateway 118 and the BM-SC 126 are connected to the IP Services 122. The IP Services 122 may include the Internet, an intranet, an IP Multimedia Subsystem (IMS), a PS Streaming Service (PSS), and/or other IP services. The BM-SC 126 may provide functions for MBMS user service provisioning and delivery. The BM-SC 126 may serve as an entry point for content provider MBMS transmission, may be used to authorize and initiate MBMS Bearer Services within a PLMN, and may be used to schedule and deliver MBMS transmissions. The MBMS Gateway 124 may be used to distribute MBMS traffic to the eNBs (e.g., 106, 108) belonging to a Multicast Broadcast Single Frequency Network (MBSFN) area broadcasting a particular service, and may be responsible for session management (start/stop) and for collecting eMBMS related charging information.

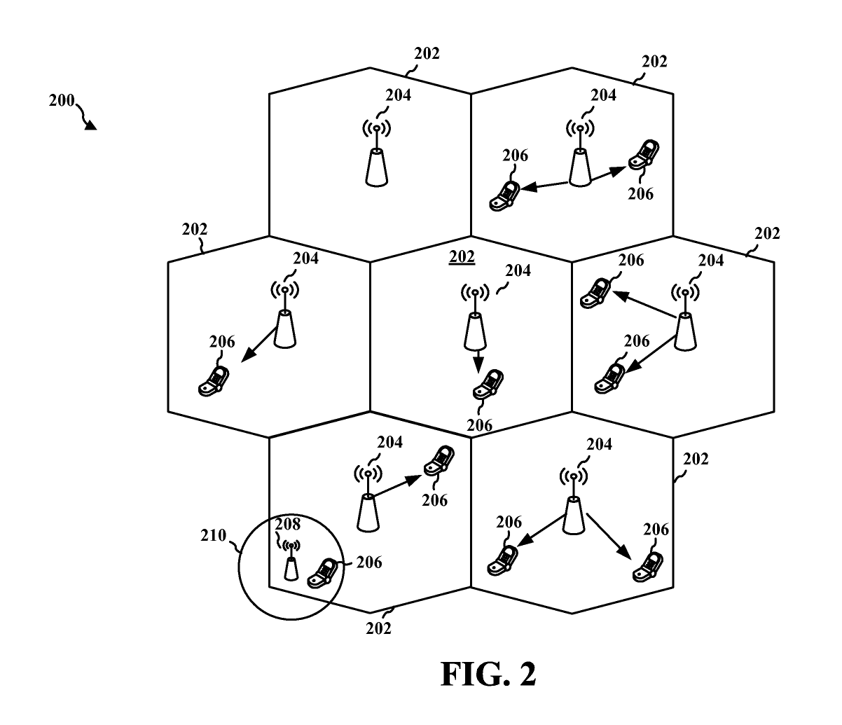

FIG. 2 is a diagram illustrating an example of an access network 200 in an LTE network architecture. In this example, the access network 200 is divided into a number of cellular regions (cells) 202. One or more lower power class eNBs 208 may have cellular regions 210 that overlap with one or more of the cells 202. The lower power class eNB 208 may be a femto cell (e.g., home eNB (HeNB)), pico cell, micro cell, or remote radio head (RRH). The macro eNBs 204 are each assigned to a respective cell 202 and are configured to provide an access point to the EPC 110 for all the UEs 206 in the cells 202. There is no centralized controller in this example of an access network 200, but a centralized controller may be used in alternative configurations. The eNBs 204 are responsible for all radio related functions including radio bearer control, admission control, mobility control, scheduling, security, and connectivity to the serving gateway 116. An eNB may support one or multiple (e.g., three) cells (also referred to as a sectors). The term “cell” can refer to the smallest coverage area of an eNB and/or an eNB subsystem serving a particular coverage area. Further, the terms “eNB,” “base station,” and “cell” may be used interchangeably herein.

The modulation and multiple access scheme employed by the access network 200 may vary depending on the particular telecommunications standard being deployed. In LTE applications, OFDM is used on the DL and SC-FDMA is used on the UL to support both frequency division duplex (FDD) and time division duplex (TDD). As those skilled in the art will readily appreciate from the detailed description to follow, the various concepts presented herein are well suited for LTE applications. However, these concepts may be readily extended to other telecommunication standards employing other modulation and multiple access techniques. By way of example, these concepts may be extended to Evolution-Data Optimized (EV-DO) or Ultra Mobile Broadband (UMB). EV-DO and UMB are air interface standards promulgated by the 3rd Generation Partnership Project 2 (3GPP2) as part of the CDMA2000 family of standards and employs CDMA to provide broadband Internet access to mobile stations. These concepts may also be extended to Universal Terrestrial Radio Access (UTRA) employing Wideband-CDMA (W-CDMA) and other variants of CDMA, such as TD-SCDMA; Global System for Mobile Communications (GSM) employing TDMA; and Evolved UTRA (E-UTRA), IEEE 802.11 (Wi-Fi), IEEE 802.16 (WiMAX), IEEE 802.20, and Flash-OFDM employing OFDMA. UTRA, E-UTRA, UMTS, LTE and GSM are described in documents from the 3GPP organization. CDMA2000 and UMB are described in documents from the 3GPP2 organization. The actual wireless communication standard and the multiple access technology employed will depend on the specific application and the overall design constraints imposed on the system.

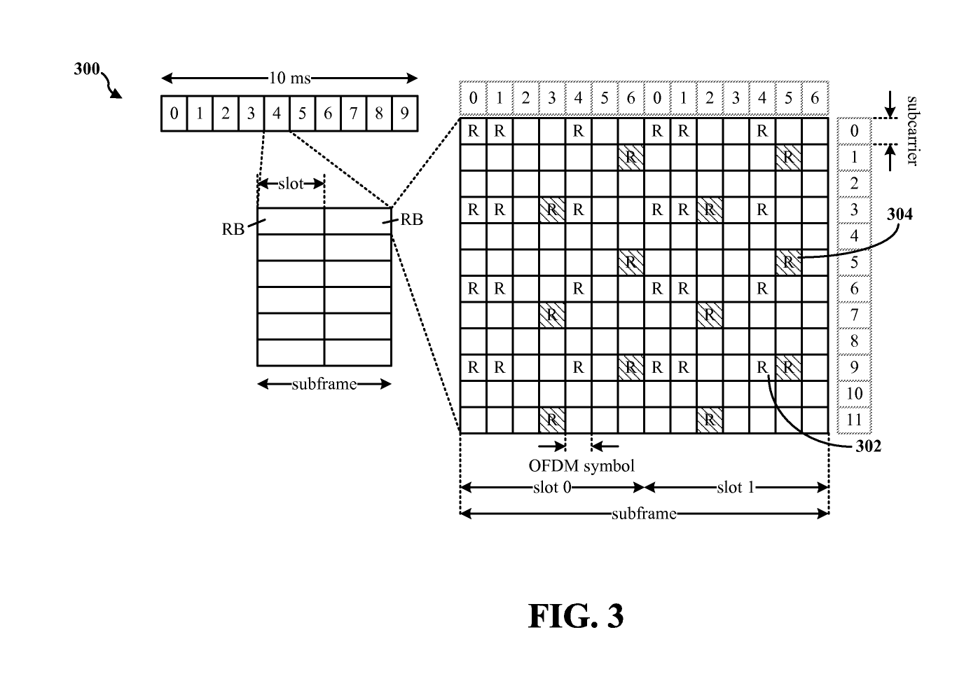

FIG. 3 is a diagram 300 illustrating an example of a DL frame structure in LTE. A frame (10 ms) may be divided into 10 equally sized subframes. Each subframe may include two consecutive time slots. A resource grid may be used to represent two time slots, each time slot including a resource block. The resource grid is divided into multiple resource elements. In LTE, for a normal cyclic prefix, a resource block contains 12 consecutive subcarriers in the frequency domain and 7 consecutive OFDM symbols in the time domain, for a total of 84 resource elements. For an extended cyclic prefix, a resource block contains 12 consecutive subcarriers in the frequency domain and 6 consecutive OFDM symbols in the time domain, for a total of 72 resource elements. Some of the resource elements, indicated as R 302, 304, include DL reference signals (DL-RS). The DL-RS include Cell-specific RS (CRS) (also sometimes called common RS) 302 and UE-specific RS (UE-RS) 304. UE-RS 304 are transmitted on the resource blocks upon which the corresponding physical DL shared channel (PDSCH) is mapped. The number of bits carried by each resource element depends on the modulation scheme. Thus, the more resource blocks that a UE receives and the higher the modulation scheme, the higher the data rate for the UE.

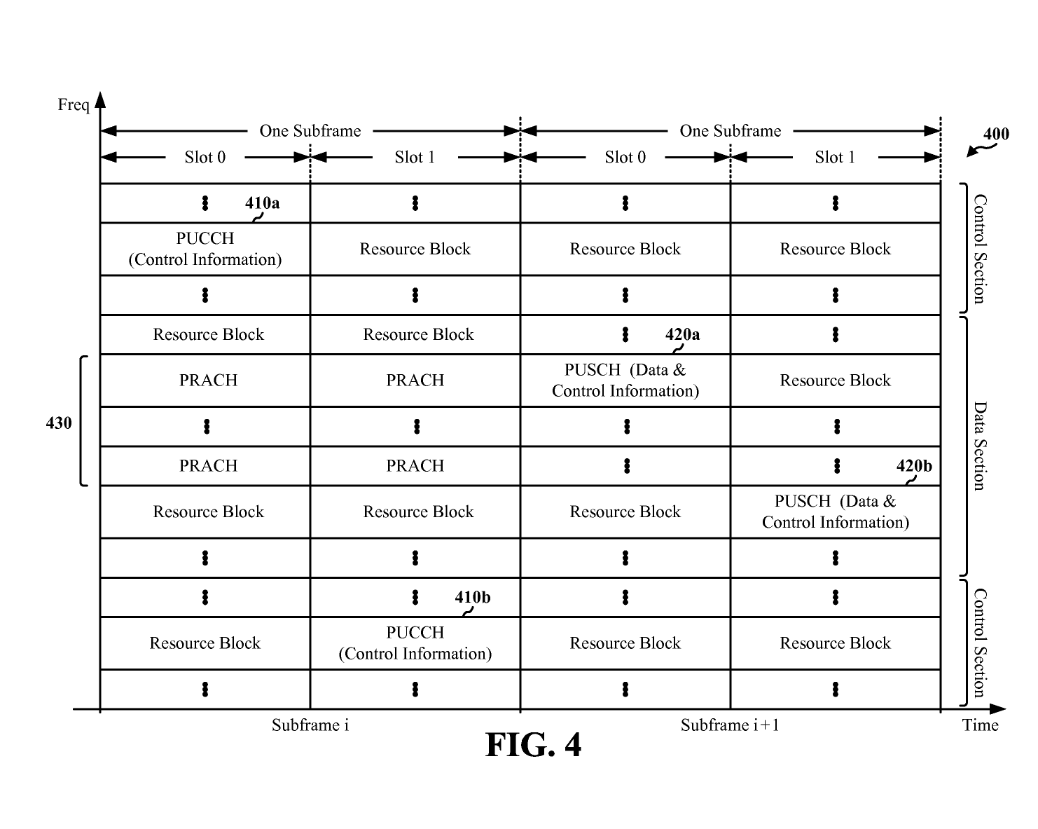

FIG. 4 is a diagram 400 illustrating an example of an UL frame structure in LTE. The available resource blocks for the UL may be partitioned into a data section and a control section. The control section may be formed at the two edges of the system bandwidth and may have a configurable size. The resource blocks in the control section may be assigned to UEs for transmission of control information. The data section may include all resource blocks not included in the control section. The UL frame structure results in the data section including contiguous subcarriers, which may allow a single UE to be assigned all of the contiguous subcarriers in the data section.

A UE may be assigned resource blocks 410a, 410b in the control section to transmit control information to an eNB. The UE may also be assigned resource blocks 420a, 420b in the data section to transmit data to the eNB. The UE may transmit control information in a physical UL control channel (PUCCH) on the assigned resource blocks in the control section. The UE may transmit data or both data and control information in a physical UL shared channel (PUSCH) on the assigned resource blocks in the data section. A UL transmission may span both slots of a subframe and may hop across frequency. A set of resource blocks may be used to perform initial system access and achieve UL synchronization in a physical random access channel (PRACH) 430.

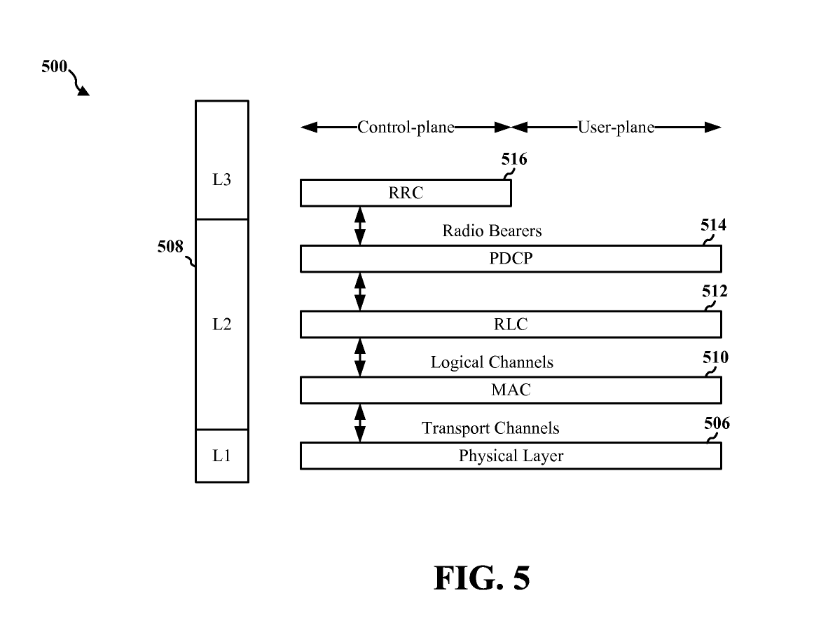

FIG. 5 is a diagram 500 illustrating an example of a radio protocol architecture for the user and control planes in LTE. The radio protocol architecture for the UE and the eNB is shown with three layers: Layer 1, Layer 2, and Layer 3. Layer 1 (L1 layer) is the lowest layer and implements various physical layer signal processing functions. The L1 layer will be referred to herein as the physical layer 506. Layer 2 (L2 layer) 508 is above the physical layer 506 and is responsible for the link between the UE and eNB over the physical layer 506.

In the user plane, the L2 layer 508 includes a media access control (MAC) sublayer 510, a radio link control (RLC) sublayer 512, and a packet data convergence protocol (PDCP) 514 sublayer, which are terminated at the eNB on the network side. Although not shown, the UE may have several upper layers above the L2 layer 508 including a network layer (e.g., IP layer) that is terminated at the PDN gateway 118 on the network side, and an application layer that is terminated at the other end of the connection (e.g., far end UE, server, etc.).

The PDCP sublayer 514 provides multiplexing between different radio bearers and logical channels. The PDCP sublayer 514 also provides header compression for upper layer data packets to reduce radio transmission overhead, security by ciphering the data packets, and handover support for UEs between eNBs. The RLC sublayer 512 provides segmentation and reassembly of upper layer data packets, retransmission of lost data packets, and reordering of data packets to compensate for out-of-order reception due to hybrid automatic repeat request (HARQ). The MAC sublayer 510 provides multiplexing between logical and transport channels. The MAC sublayer 510 is also responsible for allocating the various radio resources (e.g., resource blocks) in one cell among the UEs. The MAC sublayer 510 is also responsible for HARQ operations.

In the control plane, the radio protocol architecture for the UE and eNB is substantially the same for the physical layer 506 and the L2 layer 508 with the exception that there is no header compression function for the control plane. The control plane also includes a radio resource control (RRC) sublayer 516 in Layer 3 (L3 layer). The RRC sublayer 516 is responsible for obtaining radio resources (e.g., radio bearers) and for configuring the lower layers using RRC signaling between the eNB and the UE.

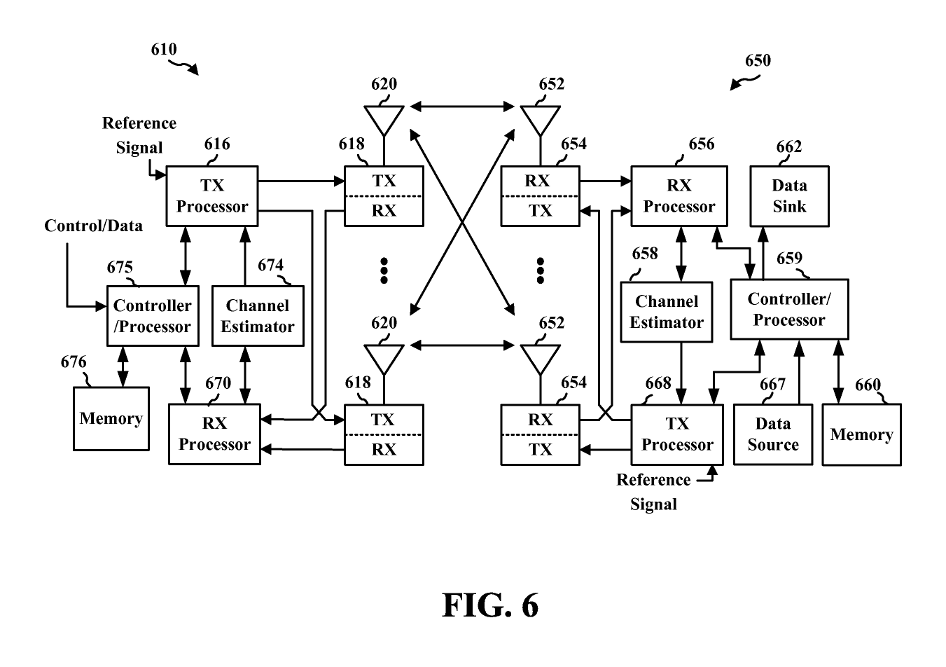

FIG. 6 is a block diagram of an eNB 610 in communication with a UE 650 in an access network. In the DL, upper layer packets from the core network are provided to a controller/processor 675. The controller/processor 675 implements the functionality of the L2 layer. In the DL, the controller/processor 675 provides header compression, ciphering, packet segmentation and reordering, multiplexing between logical and transport channels, and radio resource allocations to the UE 650 based on various priority metrics. The controller/processor 675 is also responsible for HARQ operations, retransmission of lost packets, and signaling to the UE 650.

The transmit (TX) processor 616 implements various signal processing functions for the L1 layer (i.e., physical layer). The signal processing functions include coding and interleaving to facilitate forward error correction (FEC) at the UE 650 and mapping to signal constellations based on various modulation schemes (e.g., binary phase-shift keying (BPSK), quadrature phase-shift keying (QPSK), M-phase-shift keying (M-PSK), M-quadrature amplitude modulation (M-QAM)). The coded and modulated symbols are then split into parallel streams. Each stream is then mapped to an OFDM subcarrier, multiplexed with a reference signal (e.g., pilot) in the time and/or frequency domain, and then combined together using an Inverse Fast Fourier Transform (IFFT) to produce a physical channel carrying a time domain OFDM symbol stream. The OFDM stream is spatially precoded to produce multiple spatial streams. Channel estimates from a channel estimator 674 may be used to determine the coding and modulation scheme, as well as for spatial processing. The channel estimate may be derived from a reference signal and/or channel condition feedback transmitted by the UE 650. Each spatial stream may then be provided to a different antenna 620 via a separate transmitter 618TX. Each transmitter 618TX may modulate an RF carrier with a respective spatial stream for transmission.

At the UE 650, each receiver 654RX receives a signal through its respective antenna 652. Each receiver 654RX recovers information modulated onto an RF carrier and provides the information to the receive (RX) processor 656. The RX processor 656 implements various signal processing functions of the L1 layer. The RX processor 656 may perform spatial processing on the information to recover any spatial streams destined for the UE 650. If multiple spatial streams are destined for the UE 650, they may be combined by the RX processor 656 into a single OFDM symbol stream. The RX processor 656 then converts the OFDM symbol stream from the time-domain to the frequency domain using a Fast Fourier Transform (FFT). The frequency domain signal comprises a separate OFDM symbol stream for each subcarrier of the OFDM signal. The symbols on each subcarrier, and the reference signal, are recovered and demodulated by determining the most likely signal constellation points transmitted by the eNB 610. These soft decisions may be based on channel estimates computed by the channel estimator 658. The soft decisions are then decoded and deinterleaved to recover the data and control signals that were originally transmitted by the eNB 610 on the physical channel. The data and control signals are then provided to the controller/processor 659.

The controller/processor 659 implements the L2 layer. The controller/processor can be associated with a memory 660 that stores program codes and data. The memory 660 may be referred to as a computer-readable medium. In the UL, the controller/processor 659 provides demultiplexing between transport and logical channels, packet reassembly, deciphering, header decompression, control signal processing to recover upper layer packets from the core network. The upper layer packets are then provided to a data sink 662, which represents all the protocol layers above the L2 layer. Various control signals may also be provided to the data sink 662 for L3 processing. The controller/processor 659 is also responsible for error detection using an acknowledgement (ACK) and/or negative acknowledgement (NACK) protocol to support HARQ operations.

In the UL, a data source 667 is used to provide upper layer packets to the controller/processor 659. The data source 667 represents all protocol layers above the L2 layer. Similar to the functionality described in connection with the DL transmission by the eNB 610, the controller/processor 659 implements the L2 layer for the user plane and the control plane by providing header compression, ciphering, packet segmentation and reordering, and multiplexing between logical and transport channels based on radio resource allocations by the eNB 610. The controller/processor 659 is also responsible for HARQ operations, retransmission of lost packets, and signaling to the eNB 610.

Channel estimates derived by a channel estimator 658 from a reference signal or feedback transmitted by the eNB 610 may be used by the TX processor 668 to select the appropriate coding and modulation schemes, and to facilitate spatial processing. The spatial streams generated by the TX processor 668 may be provided to different antenna 652 via separate transmitters 654TX. Each transmitter 654TX may modulate an RF carrier with a respective spatial stream for transmission.

The UL transmission is processed at the eNB 610 in a manner similar to that described in connection with the receiver function at the UE 650. Each receiver 618RX receives a signal through its respective antenna 620. Each receiver 618RX recovers information modulated onto an RF carrier and provides the information to a RX processor 670. The RX processor 670 may implement the L1 layer.

The controller/processor 675 implements the L2 layer. The controller/processor 675 can be associated with a memory 676 that stores program codes and data. The memory 676 may be referred to as a computer-readable medium. In the UL, the controller/processor 675 provides demultiplexing between transport and logical channels, packet reassembly, deciphering, header decompression, control signal processing to recover upper layer packets from the UE 650. Upper layer packets from the controller/processor 675 may be provided to the core network. The controller/processor 675 is also responsible for error detection using an ACK and/or NACK protocol to support HARQ operations.

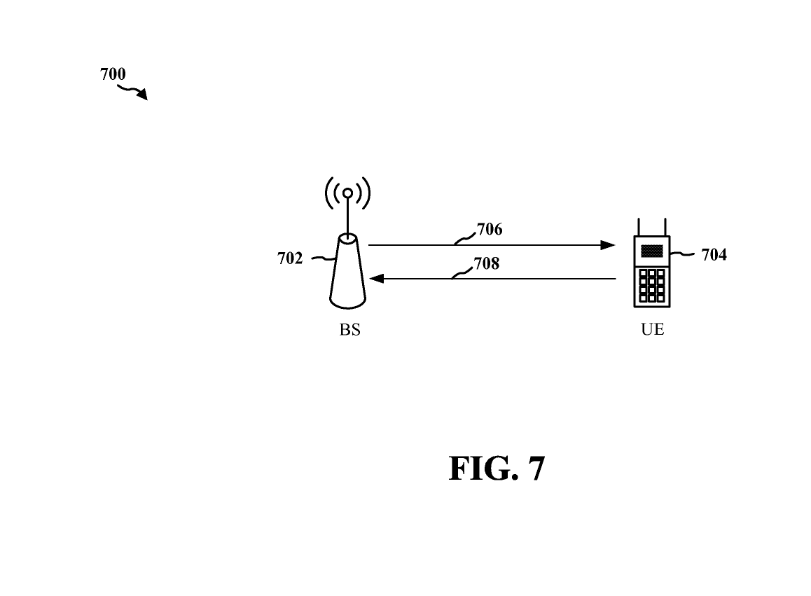

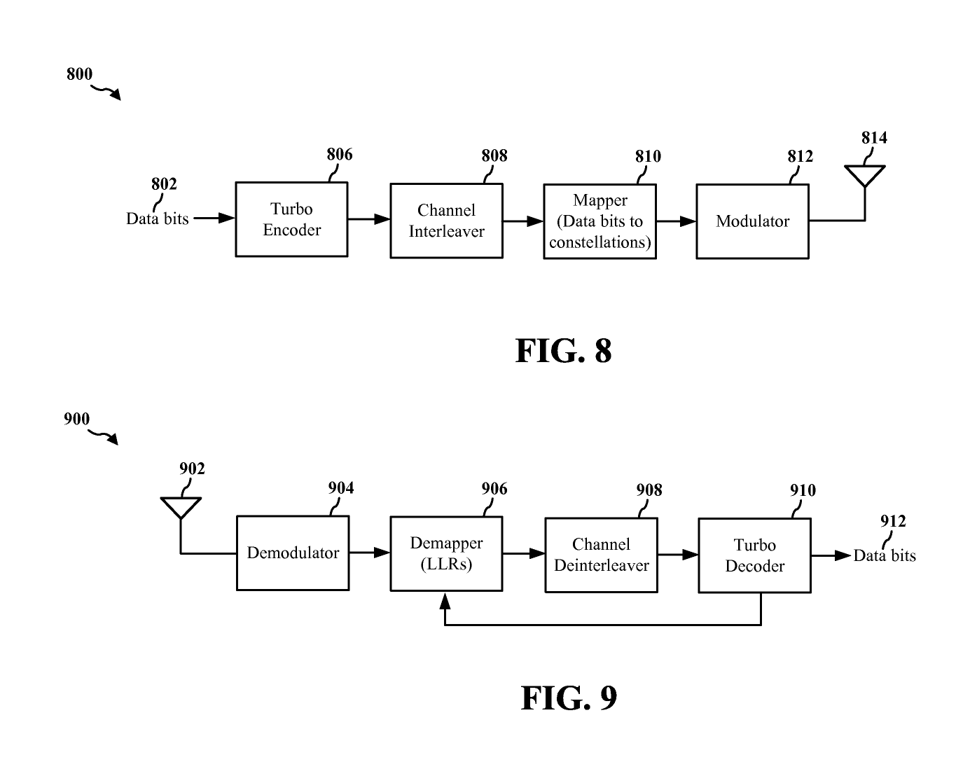

FIG. 7 is a diagram 700 illustrating a UE 704 in communication with a base station (BS) 702. As shown in FIG. 7, the UE 704 receives downlink transmissions 706 from the BS 702 and sends uplink transmissions 708 to the BS 702. In an aspect, and as described infra with respect to FIG. 8, the base station 702 may include one or more modules for processing data bits for transmission to the UE 704 in a downlink transmission and the UE 704 may include one or more modules for processing data received from the BS 702 in the downlink transmission.

FIG. 8 is a diagram 800 illustrating data processing modules in a transmitter (e.g., base station 702 in FIG. 7) in accordance with various aspects of the disclosure. FIG. 8 includes data bits 802, turbo encoder module 806, channel interleaver module 808, mapper module 810, modulator 812, and antenna 814. In an aspect, data bits 802 may be data bits of a transport block. In such aspect, the transport block may be converted into one or more code blocks based on the size of the transport block and/or channel quality between the transmitter and a receiver (e.g., UE 704 in FIG. 7). For example, if a transport block includes 5.0 kbits and a maximum size of a code block is 6.0 kbits, the transport block may be converted into a single code block. As another example, if a transport block includes 10.0 kbits and a maximum size of a code block is 6.0 kbits, the transport block may be segmented to form two code blocks. In an aspect, the maximum size of a code block is based on the code block size supported by the turbo encoder module 806. Each code block is turbo-coded using the turbo encoder module 806. The turbo-coded code block is then processed by the channel interleaver 808, mapper 810, and modulator 812 for an over-the-air (OTA) transmission to a receiver via antenna 814.

FIG. 9 is a diagram 900 illustrating data processing modules in a receiver (e.g., UE 704 in FIG. 7) in accordance with various aspects of the disclosure. FIG. 9 includes antenna 902, demodulator 904, demapper module 906, channel deinterleaver module 908, turbo decoder module 910, and data bits 912. In an aspect, an OTA transmission from a transmitter (e.g., base station 702 in FIG. 7) may be received at the antenna 902. The demodulator 904, demapper module 906, and channel deinterleaver module 908 may recover a turbo-coded code block from the OTA transmission and the turbo decoder 910 may decode the turbo-coded code block to recover a code block containing data bits 912.

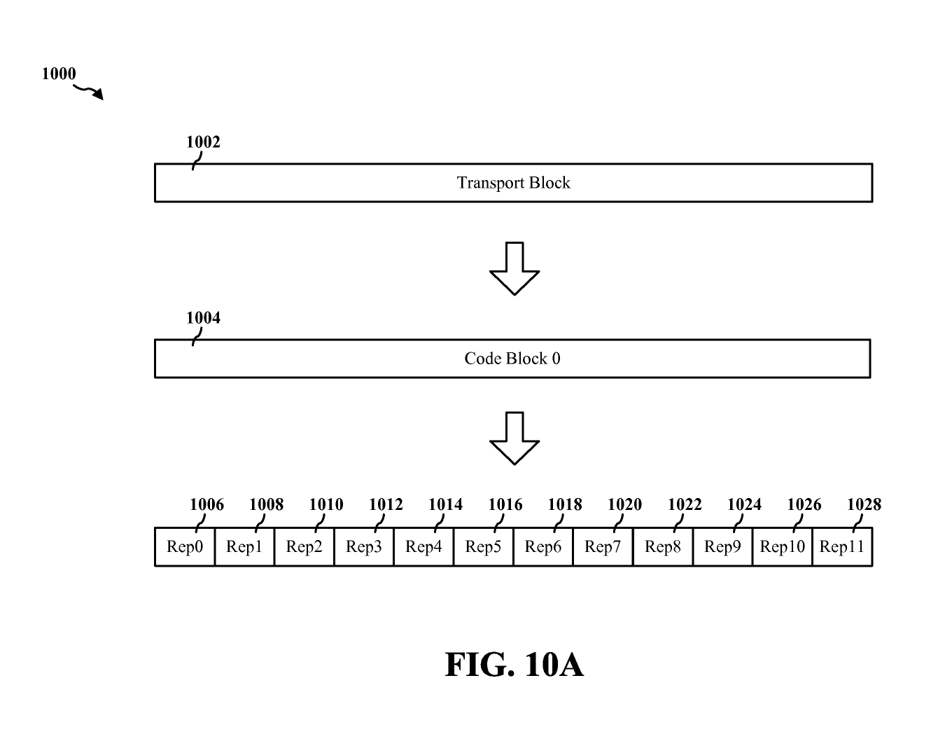

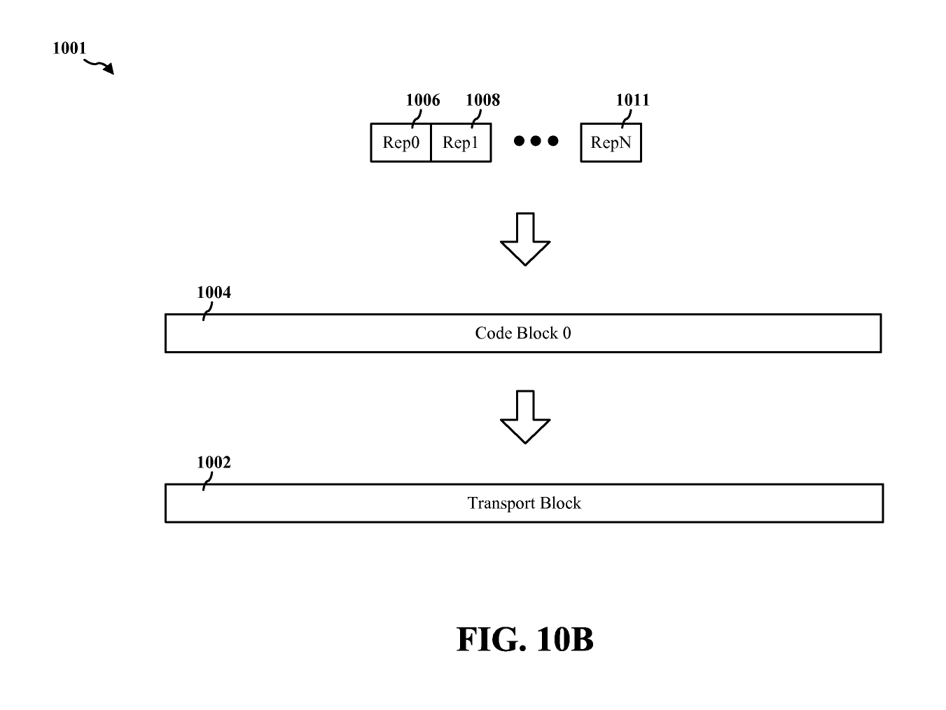

FIG. 10A is a diagram 1000 illustrating an exemplary encoding and transmission of a transport block by a transmitter in accordance with various aspects of the disclosure. In FIG. 10A, a transmitter (e.g., base station 702 in FIG. 7) may encode a transport block 1002 to generate a single code block (e.g., code block 0 1004). The transmitter may then process the code block 0 1004 (e.g., using the turbo encoder module 806, channel interleaver module 808, mapper module 810, and/or modulator 812 discussed with respect to FIG. 8) and transmit the code block 0 1004 in a number of repetitive transmissions. In the aspect of FIG. 10A, for example, the transmitter sends 12 repetitive transmissions of the code block 0 1004, such as repetition 0 1006, repetition 1 1008, repetition 2 1010, repetition 3 1012, repetition 4 1014, repetition 5 1016, repetition 6 1018, repetition 7 1020, repetition 8 1022, repetition 9 1024, repetition 10 1026, and repetition 11 1028. In an aspect, each of the repetitions may include the same information. Each of the repetitions may be transmitted using different wireless communication resources, such as different subcarrier frequencies. For example, repetition 0 1006 may be transmitted using a first subcarrier frequency, repetition 1 1008 may be transmitted using a second subcarrier frequency, and so on.

In an aspect, the transmitter may indicate the number of repetitions of a code block that are to be transmitted to a receiver prior to sending the repetitive transmissions. For example, with respect to the configuration of FIG. 10A, the transmitter may send a message in a downlink transmission to the receiver (e.g., UE 704 in FIG. 7) indicating that 12 repetitive transmissions of the code block 0 1004 will be sent by the transmitter.

FIG. 10B is a diagram 1001 illustrating an exemplary reception and decoding of a code block by a receiver in accordance with various aspects of the disclosure. As shown in FIG. 10B, a receiver (e.g., UE 704 in FIG. 7) may receive one or more of the repetitive transmissions (e.g., repetition 0 1006, repetition 1 1008, repetition N 1011) from the transmitter previously discussed with respect to FIG. 10A.

In an aspect, if the receiver successfully receives N repetitive transmissions from the transmitter, where N is less than the total number of repetitions transmitted by the transmitter (e.g., N<12), the receiver may proceed to decode the N number of successfully received repetitions in order to determine the code block 0 1004 prior to receiving the remaining repetitions transmitted by the transmitter. For example, if the receiver successfully receives repetition 0 1006, repetition 1 1008, and repetition 2 1010, the receiver may proceed to decode the received repetitive transmissions prior to receiving repetition 3 1012, repetition 4 1014, repetition 5 1016, repetition 6 1018, repetition 7 1020, repetition 8 1022, repetition 9 1024, repetition 10 1026, and repetition 11 1028. Upon determining the code block 0 1004, the receiver may decode the code block 0 1004 to determine the transport block 1002.

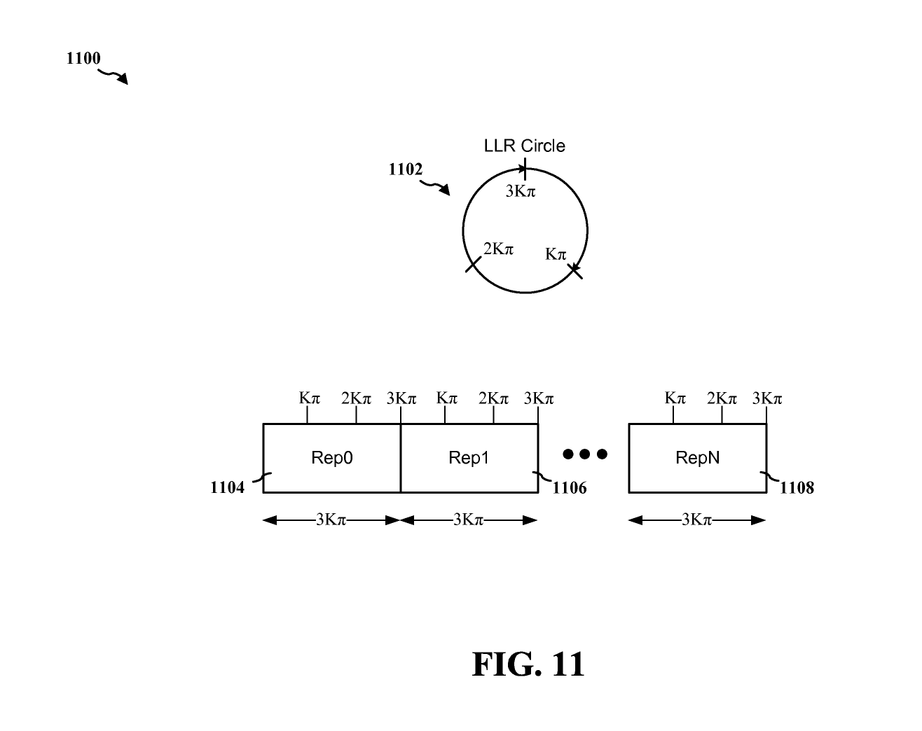

FIG. 11 is a diagram 1100 illustrating log likelihood ratios (LLRs) determined for a code block received in an OTA transmission. An LLR represents the logarithm of the ratio of the probabilities of a bit taking its two possible values. For example, the LLR of a bit k may be determined using equation 1:

$${LLR}_{k} = log \frac{P ( k = 1 )}{P ( k = - 1 )} \qquad ( equation 1 )$$

where P(k=1) represents the probability that the value of bit k is 1 and P(k=−1 represents the probability that the value of bit k is −1. The sign of the LLR gives an estimate of the information bit k (e.g., LLR≧0→0, and LLR<0→1), and the magnitude indicates the reliability of the estimate of the bit k. FIG. 11 shows an LLR circle 1102, which is a graphic representation of the LLRs determined for a code block that is turbo-coded with a ⅓ code rate. In FIG. 11, Kπ is defined as the number of systematic bits in a code block. Therefore, for a ⅓ code rate and full incremental redundancy (IR) buffer, the total number of LLRs will be 3Kπ per repetition of a code block. As shown in FIG. 11, for example, 3Kπ LLRs may be determined for repetition 0 1104 of a code block (e.g., code block 0 1004 in FIGS. 10A and 10B), 3Kπ LLRs may be determined for repetition 1 1106 of the code block, up to repetition N 1108 of the code block.

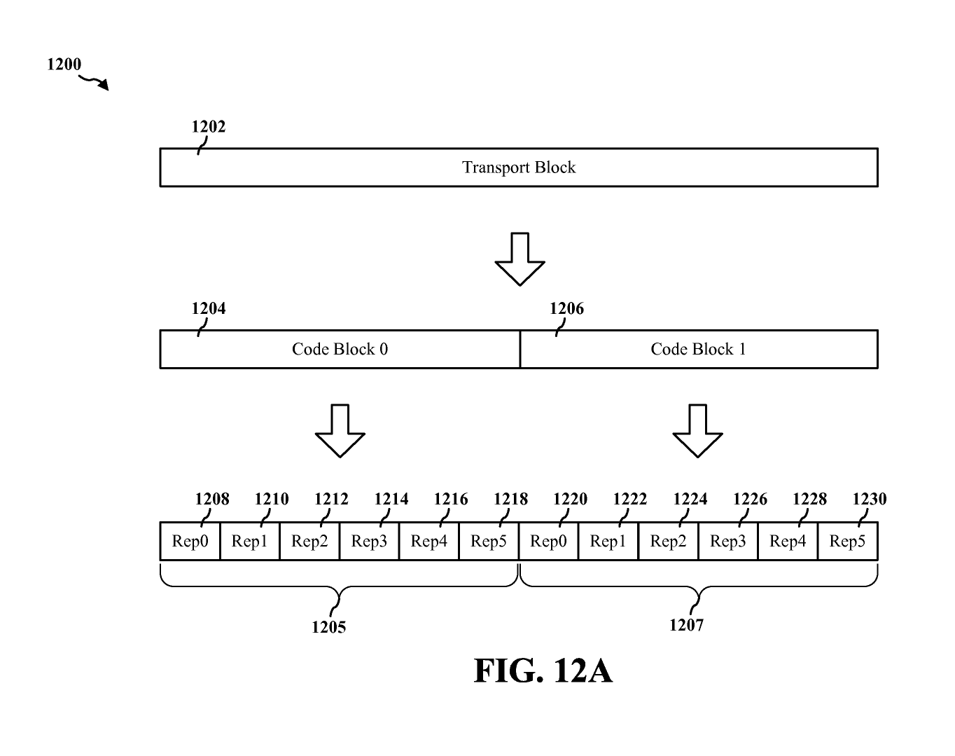

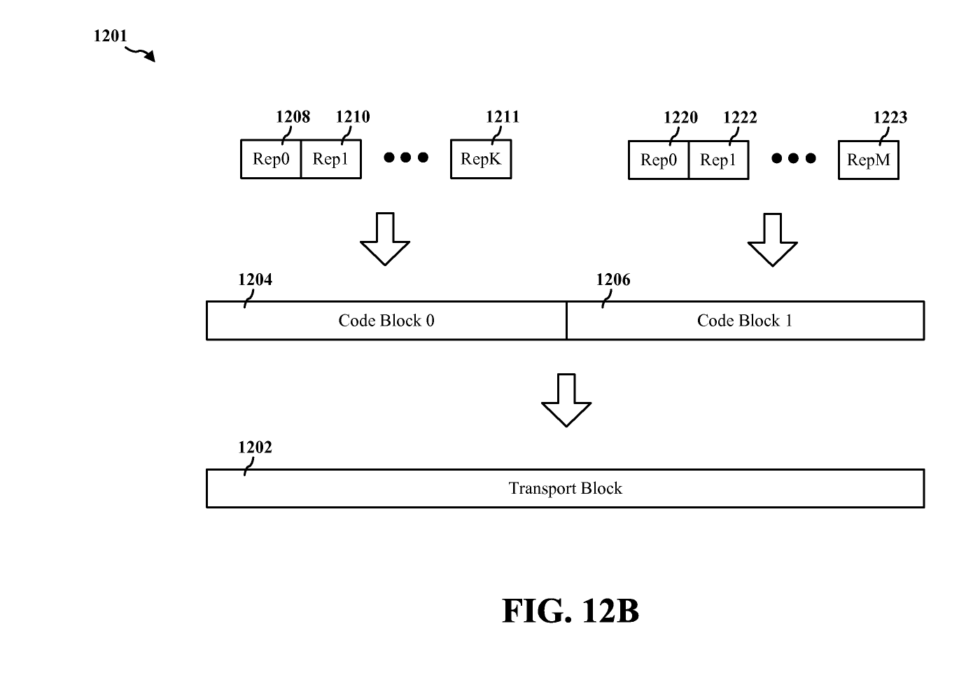

FIG. 12A is a diagram 1200 illustrating an exemplary encoding and transmission of a transport block by a transmitter in accordance with various aspects of the disclosure. As shown in FIG. 12A, a transmitter (e.g., base station 702 in FIG. 7) may segment and encode a transport block 1202 to generate two code blocks (e.g., code block 0 1204 and code block 1 1206). While only two code blocks per transport block are depicted in FIG. 12A, the number of code blocks in each transport block is configurable (e.g., based on channel quality, bandwidth, etc.), as are the number for repetitions per code block.

The transmitter may then process each code block (e.g., using the turbo encoder module 806, channel interleaver module 808, mapper module 810, and/or modulator 812 discussed with respect to FIG. 8) and transmit each code block in a number of repetitive transmissions. In the aspect of FIG. 12A, for example, the transmitter sends a first set of repetitive transmissions 1205 of the code block 0 1204, where the first set of repetitive transmissions 1205 includes repetition 0 1208, repetition 1 1210, repetition 2 1212, repetition 3 1214, repetition 4 1216, and repetition 5 1218. The transmitter further sends a second set of repetitive transmissions 1207 of the code block 1 1206, where the second set of repetitive transmissions 1207 includes repetition 0 1220, repetition 1 1222, repetition 2 1224, repetition 3 1226, repetition 4 1228, and repetition 5 1230. In an aspect, each repetition of a code block may include the same information. For example, each repetition in the first set of repetitive transmissions 1205 may include the same information, and each repetition in the second set of repetitive transmissions 1207 may include the same information. In such aspect, each repetition of a code block may be transmitted using different wireless communication resources, such as different subcarrier frequencies. For example, repetition 0 1208 may be transmitted using a first subcarrier frequency, repetition 1 1210 may be transmitted using a second subcarrier frequency, and so on.

In an aspect, the transmitter may indicate the number of repetitions of a code block that are to be transmitted to a receiver prior to sending the repetitive transmissions. For example, with respect to the configuration of FIG. 12A, the transmitter may send a message in a downlink transmission to the receiver (e.g., UE 704 in FIG. 7) indicating that six repetitive transmissions of the code block 0 1204 will be sent by the transmitter and/or indicating that six repetitive transmissions of the code block 1 1206 will be sent by the transmitter.

FIG. 12B is a diagram 1201 illustrating an exemplary reception and decoding of code blocks by a receiver in accordance with various aspects of the disclosure. As shown in FIG. 12B, a receiver (e.g., UE 704 in FIG. 7) may receive a number of the repetitive transmissions (e.g., repetition 0 1208, repetition 1 1210, repetition K 1211 associated with code block 0 1204 and repetition 0 1220, repetition 1 1222, and repetition M 1223 associated with code block 1 1206) from the transmitter previously discussed with respect to FIG. 12A. While only two code blocks per transport block are depicted in FIG. 12B, the number of code blocks in each transport block is configurable (e.g., based on channel quality, bandwidth, etc.), as are the number for repetitions per code block.

In an aspect, if the receiver successfully receives K repetitive transmissions from the transmitter for a corresponding code block (e.g., code block 0 1204), where K is less than the total number of repetitions transmitted by the transmitter for the corresponding code block (e.g., K<6), the receiver may proceed to decode the K number of successfully received repetitions in order to determine the code block 0 1204 prior to receiving the remaining repetitions transmitted by the transmitter. For example, if the receiver successfully receives repetition 0 1208, repetition 1 1210, and repetition 2 1212, the receiver may proceed to decode the received repetitive transmissions prior to receiving repetition 3 1214, repetition 4 1216, and repetition 5 1218. In such example, if the receiver successfully receives M repetitive transmissions from the transmitter for a corresponding code block (e.g., code block 1 1206), where M is less than the total number of repetitions transmitted by the transmitter for the corresponding code block (e.g., M<6), the receiver may proceed to decode the M number of successfully received repetitions in order to determine the code block 1 1206 prior to receiving the remaining repetitions transmitted by the transmitter. For example, if the receiver successfully receives repetition 0 1220, repetition 1 1222, and repetition 2 1224, the receiver may proceed to decode the received repetitive transmissions prior to receiving repetition 3 1226, repetition 4 1228, and repetition 5 1230. Upon determining the code block 0 1204 and the code block 1 1206, the receiver may decode the code blocks 1204, 1206 to determine the transport block 1202.

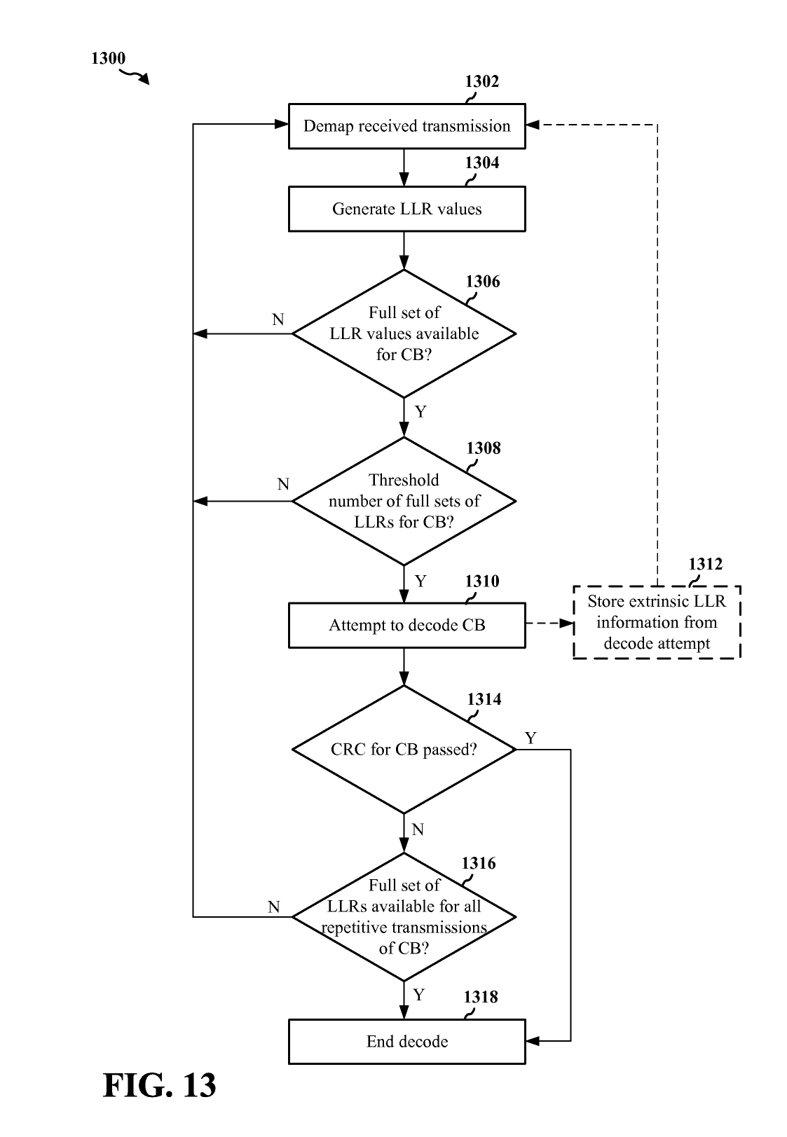

FIG. 13 is a flow chart 1300 of an algorithm for decoding a code block in accordance with various aspects of the disclosure. The algorithm of FIG. 13 may be performed by a receiver (e.g., UE 704 in FIG. 7). It should be understood that the operations indicated with dotted lines in FIG. 13 represent operations for alternative aspects.

At 1302, the receiver demaps a received transmission. The received transmission may be a repetition of a code block received from a transmitter (e.g., BS 702 in FIG. 7), such as repetition 0 1006 of the code block 0 1004 previously described with respect to FIGS. 10A and 10B. At 1304, the receiver generates LLR values for the received repetition of the code block (e.g., code block 0 1004). For example, for a ⅓ code rate and full IR buffer, the total number of LLRs may be 3Kπ, where Kπ represents the number of systematic bits in a code block.

At 1306, the receiver determines whether a full set of LLR values are available for the code block. For example, with reference to FIG. 11, in order to obtain a full set of LLR values (also referred to as a full circle of LLR values) for repetition 0 1104 having a ⅓ code rate, 3Kπ LLR values are needed.

At 1308, if a full set of LLR values are available (1306) then the receiver determines whether a threshold number of full sets of LLRs are available for the code block. For example, the threshold number of full sets of LLRs may be three. In such example, if a full set of LLRs is available for repetition 0 1006, repetition 1 1008, and repetition 2 1010, the receiver may attempt to decode the code block at operation 1310. In an aspect, the receiver may perform a turbo-decoding procedure to decode the code block.

At 1312, the receiver may store extrinsic LLR information from the decode attempt and may return to operation 1302. At 1314, the receiver performs a cyclic redundancy check (CRC) for the code block and determines whether the CRC for the code block is successful. If the CRC for the code block is not successful (1314), the transmitter determines whether a full set of LLRs are available for all repetitive transmissions of the code block.

At 1318, if a full set of LLRs are available for all repetitive transmissions of the code block (1316) or if the CRC for the code block is successful (1314), the decoding operation is halted. If the receiver determines that a full set of LLR values are not available for the code block (1306), determines that a threshold number of full sets of LLRs are not available for the code block (1308), or determines that a full set of LLRs are not available for all repetitive transmissions of the code block, the receiver returns to operation 1302.

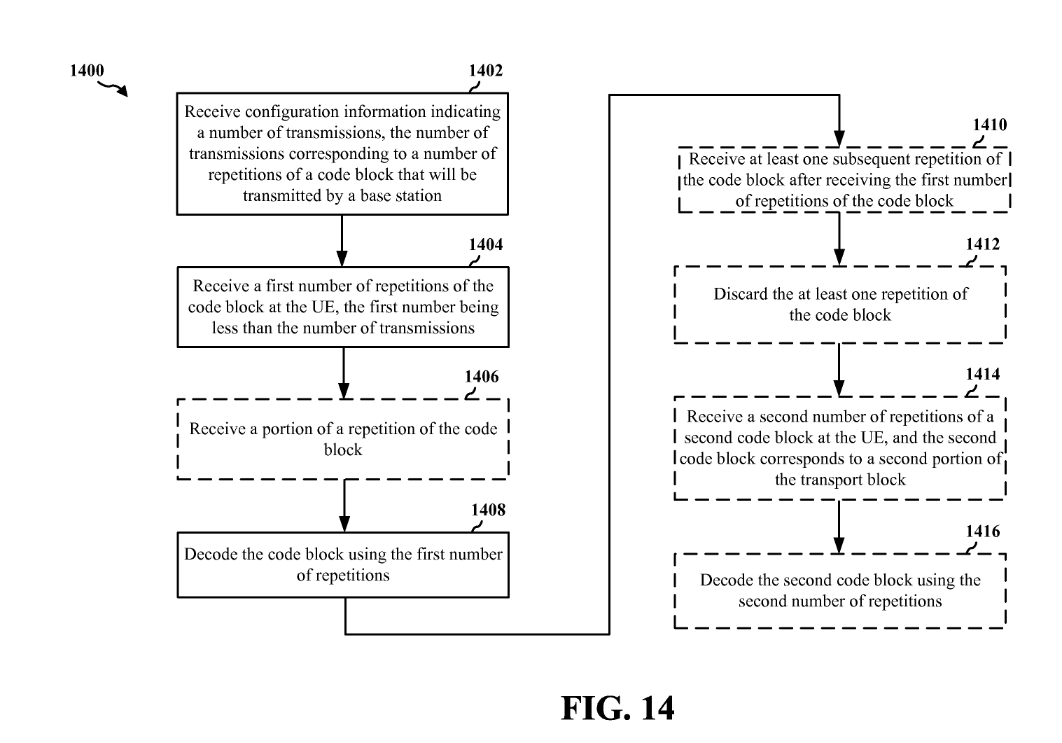

FIG. 14 is a flow chart 1400 of a method of wireless communication. The method may be performed by a UE (e.g., the UE 704, the apparatus 1502/1502′). It should be understood that the operations indicated with dotted lines represent optional operations. As such, steps 1406, 1410, 1412, 1414 and 1416 represent optional steps in flow chart 1400.

At 1402, the UE receives configuration information indicating a number of transmissions, the number of transmissions corresponding to a number of repetitions of a code block that will be transmitted by a base station. In an aspect, the code block corresponds to an entire a transport block. For example, with reference to FIGS. 10A and 10B, the code block 0 1004 corresponds to transport block 1002. In an aspect, the code block corresponds to a portion of a transport block, and the transport block corresponds to a number of code blocks. For example, with reference to FIGS. 12A and 12B, transport block 1202 corresponds to code block 0 1204 and code block 1 1206, where code block 0 1204 corresponds to one portion of transport block 1202 and code block 1 1206 corresponds to another portion of transport block 1202.

At 1404, the UE receives a first number of repetitions of the code block, the first number being less than the number of transmissions. For example, with reference to FIGS. 10A and 10B, the UE may successfully receive repetition 0 1006, repetition 1 1008, and repetition 2 1010 for code block 0 1004 without successfully receiving repetition 3 1012, repetition 4 1014, repetition 5 1016, repetition 6 1018, repetition 7 1020, repetition 8 1022, repetition 9 1024, repetition 10 1026, and repetition 11 1028.

At 1406, the UE receives a portion of a repetition of the code block. For example, with reference to FIGS. 10A and 10B, the UE may receive a portion of repetition 3 1012 for code block 0 1004 after receiving repetition 0 1006, repetition 1 1008, and repetition 2 1010.

At 1408, the UE decodes the code block using the first number of repetitions. In an aspect, the UE decodes the code block using the first number of repetitions and a portion of a repetition of the code block which is received subsequent to the first number of repetitions. In an aspect, the UE decodes the code block by iteratively decoding the first number of repetitions to determine the code block. For example, if the UE successfully receives repetition 0 1006, repetition 1 1008, and repetition 2 1010, the UE may proceed to decode the received repetitive transmissions to determine the code block 0 1004 using an iterative decoding procedure (e.g., turbo decoding). In such example, the UE may begin decoding prior to receiving repetition 3 1012, repetition 4 1014, repetition 5 1016, repetition 6 1018, repetition 7 1020, repetition 8 1022, repetition 9 1024, repetition 10 1026, and/or repetition 11 1028. In an aspect, the UE may implement the algorithm discussed supra with respect to FIG. 13 based on the successfully received repetitive transmissions to decode the corresponding code block (e.g., code block 0 1004). Upon determining the code block (e.g., code block 0 1004), the UE may decode the code block to determine the corresponding transport block (e.g., transport block 1002).

At 1410, the UE receives at least one subsequent repetition of the code block after receiving the first number of repetitions of the code block. For example, with reference to FIGS. 10A and 10B, the UE may further receive repetition 3 1012, repetition 4 1014, repetition 5 1016, repetition 6 1018, repetition 7 1020, repetition 8 1022, repetition 9 1024, repetition 10 1026, and/or repetition 11 1028, after successfully decoding code block 0 1004 based on received repetition 0 1006, repetition 1 1008, and repetition 2 1010.

At 1412, the UE discards the at least one repetition of the code block. For example, with reference to FIGS. 10A and 10B, after successfully decoding code block 0 1004 based on received repetition 0 1006, repetition 1 1008, and repetition 2 1010, the UE may discard repetition 3 1012, repetition 4 1014, repetition 5 1016, repetition 6 1018, repetition 7 1020, repetition 8 1022, repetition 9 1024, repetition 10 1026, and/or repetition 11 1028 received from the transmitter.

At 1414, the UE receives a second number of repetitions of a second code block. In an aspect, the code block is a first code block, the first code block corresponds to a first portion of a transport block, and the transport block corresponds to a number of code blocks. In such aspect, the second code block corresponds to a second portion of the transport block. For example, with reference to FIG. 12B, the UE may successfully receive K repetitive transmissions from the transmitter for a corresponding first code block (e.g., code block 0 1204), where K is less than the total number of repetitions transmitted by the transmitter for the corresponding first code block (e.g., K<6). In such example, the UE may successfully receive M repetitive transmissions from the transmitter for a corresponding second code block (e.g., code block 1 1206), where M is less than the total number of repetitions transmitted by the transmitter for the corresponding second code block (e.g., M<6). Therefore, in one example with reference to FIG. 12B, the UE may successfully receive repetition 0 1208, repetition 1 1210, and repetition 2 1212 for code block 0 1204, without receiving repetition 3 1214, repetition 4 1216, and repetition 5 1218, and may successfully receive repetition 0 1220, repetition 1 1222, and repetition 2 1224 for code block 1 1206, without receiving repetition 3 1226, repetition 4 1228, and repetition 5 1230. In an aspect, the first number or repetitions is equal to the second number of repetitions. For example, with reference to FIG. 12B, the K number of repetitive transmissions may be equal to the M number of repetitive transmissions. In an aspect, the first number is not equal to the second number and the second number is less than the number of transmissions. For example, with reference to FIGS. 12A and 12B, the K number of repetitive transmissions received by the UE may not be equal to the M number of repetitive transmissions received by the UE, and the M number of repetitions received by the UE may be less than the total number of repetitions (e.g., M<6) transmitted by the transmitter for a corresponding code block (e.g., the second set of repetitions 1207 for code block 1 1206). In an aspect, the second number is equal to the number of transmissions. For example, with reference to FIGS. 12A and 12B, the M number of repetitive transmissions may be equal to the number of repetitions in the second set of repetitive transmissions 1207.

At 1416, the UE decodes the second code block using the second number of repetitions. In an aspect, the UE receives at least one subsequent repetition of the second code block after receiving the second number of repetitions of the second code block. For example, with reference to FIGS. 12A and 12B, the UE may further receive repetition 3 1226, repetition 4 1228, and repetition 5 1230 after successfully decoding code block 1 1206 based on received repetition 0 1220, repetition 1 1222, and repetition 2 1224. In such aspect, the UE discards the at least one repetition of the second code block. For example, with reference to FIGS. 12A and 12B, after successfully decoding code block 1 1206 based on received repetition 0 1220, repetition 1 1222, and repetition 2 1224, the UE may discard repetition 3 1226, repetition 4 1228, and/or repetition 5 1230 received from the transmitter.

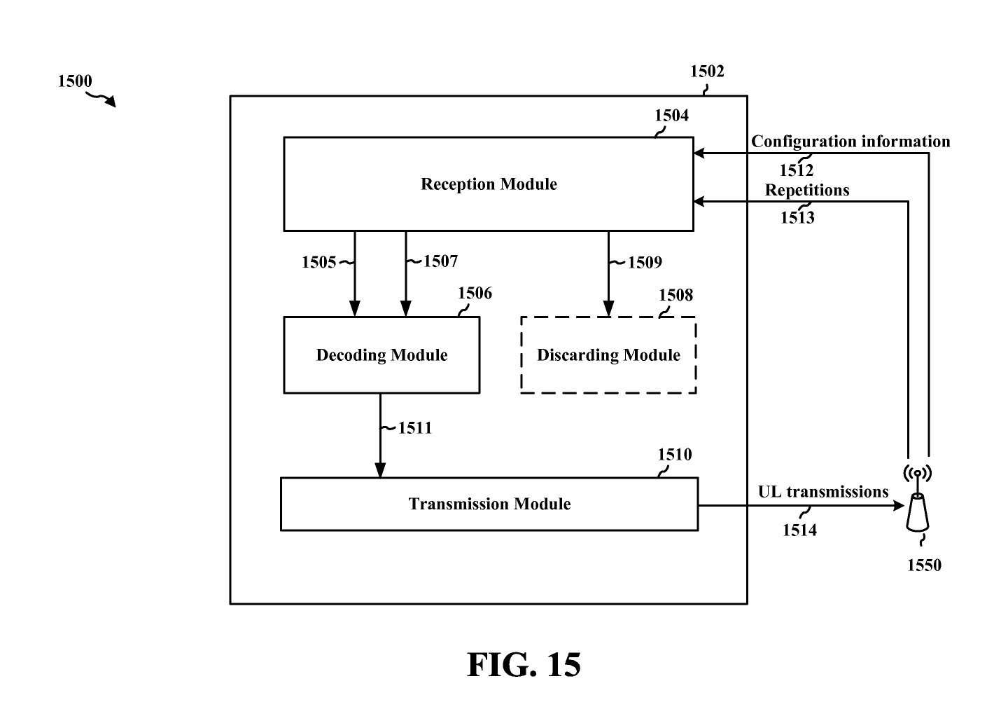

FIG. 15 is a conceptual data flow diagram 1500 illustrating the data flow between different modules/means/components in an exemplary apparatus 1502. The apparatus may be a UE. The apparatus includes a module 1504 that receives configuration information (e.g., via signal 1512) indicating a number of transmissions, receives a first number of repetitions (e.g., via signal 1513) of the code block at the UE, receives a portion of a repetition of the code block, receives at least one subsequent repetition (e.g., via signal 1513) of the code block after receiving the first number of repetitions of the code block, and receives a second number of repetitions (e.g., via signal 1513) of a second code block, where the second code block corresponds to a second portion of the transport block. The apparatus further includes a module 1506 that decodes the code block using the first number of repetitions. The module 1506 further decodes the second code block using the second number of repetitions. The module 1506 receives the first number of repetitions and/or a portion of a repetition of the code block via signal 1505 and receives the second number of repetitions via signal 1507. The apparatus further includes a module 1508 that discards the at least one repetition of the code block. The module 1508 receives the at least one repetition of the code block via signal 1509. The apparatus further includes a module 1510 that transmits uplink transmissions 1514 to the base station 1550. In an aspect, the uplink transmissions are based on a decoded code block 1511 from the module 1506.

The apparatus may include additional modules that perform each of the blocks of the algorithm in the aforementioned flow chart of FIG. 11. As such, each block in the aforementioned flow chart of FIG. 11 may be performed by a module and the apparatus may include one or more of those modules. The modules may be one or more hardware components specifically configured to carry out the stated processes/algorithm, implemented by a processor configured to perform the stated processes/algorithm, stored within a computer-readable medium for implementation by a processor, or some combination thereof.

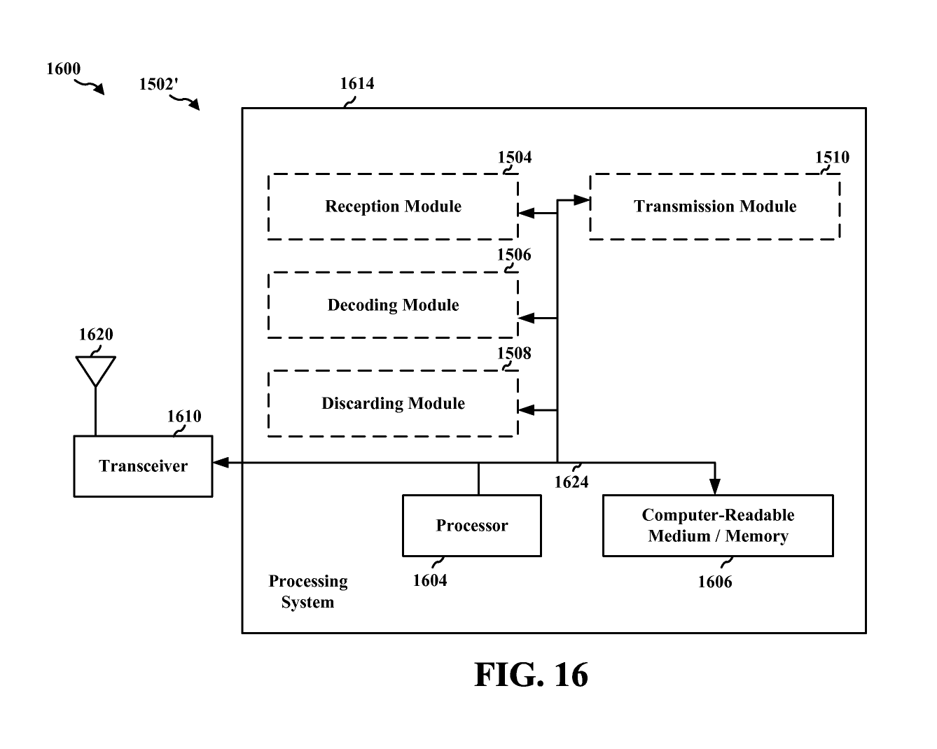

FIG. 16 is a diagram 1600 illustrating an example of a hardware implementation for an apparatus 1502′ employing a processing system 1614. The processing system 1614 may be implemented with a bus architecture, represented generally by the bus 1624. The bus 1624 may include any number of interconnecting buses and bridges depending on the specific application of the processing system 1614 and the overall design constraints. The bus 1624 links together various circuits including one or more processors and/or hardware modules, represented by the processor 1604, the modules 1504, 1506, 1508, and 1510, and the computer-readable medium/memory 1606. The bus 1624 may also link various other circuits such as timing sources, peripherals, voltage regulators, and power management circuits, which are well known in the art, and therefore, will not be described any further.

The processing system 1614 may be coupled to a transceiver 1610. The transceiver 1610 is coupled to one or more antennas 1620. The transceiver 1610 provides a means for communicating with various other apparatus over a transmission medium. The transceiver 1610 receives a signal from the one or more antennas 1620, extracts information from the received signal, and provides the extracted information to the processing system 1614, specifically the reception module 1504. In addition, the transceiver 1610 receives information from the processing system 1614, specifically the transmission module 1510, and based on the received information, generates a signal to be applied to the one or more antennas 1620. The processing system 1614 includes a processor 1604 coupled to a computer-readable medium/memory 1606. The processor 1604 is responsible for general processing, including the execution of software stored on the computer-readable medium/memory 1606. The software, when executed by the processor 1604, causes the processing system 1614 to perform the various functions described supra for any particular apparatus. The computer-readable medium/memory 1606 may also be used for storing data that is manipulated by the processor 1604 when executing software. The processing system further includes at least one of the modules 1504, 1506, 1508, and 1510. The modules may be software modules running in the processor 1604, resident/stored in the computer readable medium/memory 1606, one or more hardware modules coupled to the processor 1604, or some combination thereof. The processing system 1614 may be a component of the UE 650 and may include the memory 660 and/or at least one of the TX processor 668, the RX processor 656, and the controller/processor 659.

In one configuration, the apparatus 1502/1502′ for wireless communication includes means for receiving configuration information indicating a number of transmissions, the number of transmissions corresponding to a number of repetitions of a code block that will be transmitted by a base station, means for receiving a first number of repetitions of the code block at the UE, the first number being less than the number of transmissions, means for decoding the code block using the first number of repetitions, means for receiving at least one subsequent repetition of the code block after receiving the first number of repetitions of the code block, means for discarding the at least one repetition of the code block, means for receiving a second number of repetitions of a second code block at the UE, the second code block corresponds to a second portion of the transport block, and means for decoding the second code block using the second number of repetitions. The aforementioned means may be one or more of the aforementioned modules of the apparatus 1502 and/or the processing system 1614 of the apparatus 1502′ configured to perform the functions recited by the aforementioned means. As described supra, the processing system 1614 may include the TX Processor 668, the RX Processor 656, and the controller/processor 659. As such, in one configuration, the aforementioned means may be the TX Processor 668, the RX Processor 656, and the controller/processor 659 configured to perform the functions recited by the aforementioned means.

It is understood that the specific order or hierarchy of blocks in the processes/flow charts disclosed is an illustration of exemplary approaches. Based upon design preferences, it is understood that the specific order or hierarchy of blocks in the processes/flow charts may be rearranged. Further, some blocks may be combined or omitted. The accompanying method claims present elements of the various blocks in a sample order, and are not meant to be limited to the specific order or hierarchy presented.

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein, but is to be accorded the full scope consistent with the language claims, wherein reference to an element in the singular is not intended to mean “one and only one” unless specifically so stated, but rather “one or more.” The word “exemplary” is used herein to mean “serving as an example, instance, or illustration.” Any aspect described herein as “exemplary” is not necessarily to be construed as preferred or advantageous over other aspects. Unless specifically stated otherwise, the term “some” refers to one or more. Combinations such as “at least one of A, B, or C,” “at least one of A, B, and C,” and “A, B, C, or any combination thereof” include any combination of A, B, and/or C, and may include multiples of A, multiples of B, or multiples of C. Specifically, combinations such as “at least one of A, B, or C,” “at least one of A, B, and C,” and “A, B, C, or any combination thereof” may be A only, B only, C only, A and B, A and C, B and C, or A and B and C, where any such combinations may contain one or more member or members of A, B, or C. All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed as a means plus function unless the element is expressly recited using the phrase “means for.”

What is claimed is:

1. A method of wireless communication comprising:
receiving configuration information indicating a number of transmissions, the number of transmissions corresponding to a number of repetitions of a code block that will be transmitted by a base station;
receiving a first number of repetitions of the code block at the UE, the first number being less than the number of transmissions; and
decoding the code block using the first number of repetitions.

2. The method of claim 1, further comprising receiving a portion of a repetition of the code block, and wherein the decoding further uses the portion of the repetition of the code block.

3. The method of claim 1, further comprising:
receiving at least one subsequent repetition of the code block after receiving the first number of repetitions of the code block; and
discarding the at least one repetition of the code block.

4. The method of claim 1, the decoding comprising iterative decoding of the code block.

5. The method of claim 1, wherein the code block corresponds to an entire a transport block.

6. The method of claim 1, wherein the code block corresponds to a portion of a transport block, and the transport block comprises a plurality of code blocks.

7. The method of claim 1, wherein the code block is a first code block, the first code block corresponds to a first portion of a transport block, and the transport block comprises a plurality of code blocks, the method further comprising:
receiving a second number of repetitions of a second code block at the UE, and the second code block corresponds to a second portion of the transport block; and
decoding the second code block using the second number of repetitions.

8. The method of claim 7, wherein the first number of repetitions is equal to the second number of repetitions.

9. The method of claim 7, wherein the first number is not equal to the second number and the second number is less than the number of transmissions.

10. The method of claim 7, wherein the second number is equal to the number of transmissions.

11. An apparatus for wireless communication, comprising:
means for receiving configuration information indicating a number of transmissions, the number of transmissions corresponding to a number of repetitions of a code block that will be transmitted by a base station;
means for receiving a first number of repetitions of the code block at the UE, the first number being less than the number of transmissions; and
means for decoding the code block using the first number of repetitions.

12. The apparatus of claim 11, further comprising means for receiving a portion of a repetition of the code block, and wherein the means for decoding is configured to use the portion of the repetition of the code block.

13. The apparatus of claim 11, further comprising:
means for receiving at least one subsequent repetition of the code block after receiving the first number of repetitions of the code block; and
means for discarding the at least one repetition of the code block.

14. The apparatus of claim 11, wherein the code block corresponds to an entire a transport block.

15. The apparatus of claim 11, wherein the code block corresponds to a portion of a transport block, and the transport block comprises a plurality of code blocks.

16. The apparatus of claim 11, wherein the code block is a first code block, the first code block corresponds to a first portion of a transport block, and the transport block comprises a plurality of code blocks, the method further comprising:
means for receiving a second number of repetitions of a second code block at the UE, and the second code block corresponds to a second portion of the transport block; and
means for decoding the second code block using the second number of repetitions.

17. The apparatus of claim 16, wherein the first number of repetitions is equal to the second number of repetitions.

18. The apparatus of claim 16, wherein the first number is not equal to the second number and the second number is less than the number of transmissions.

19. The apparatus of claim 16, wherein the second number is equal to the number of transmissions.

20. An apparatus for wireless communication, comprising:
a memory; and
at least one processor coupled to the memory and configured to:
receive configuration information indicating a number of transmissions, the number of transmissions corresponding to a number of repetitions of a code block that will be transmitted by a base station;
receive a first number of repetitions of the code block at the UE, the first number being less than the number of transmissions; and
decode the code block using the first number of repetitions.

21. The apparatus of claim 20, the at least one processor further configured to receive a portion of a repetition of the code block and to decode the code block further using the portion of the repetition of the code block.

22. The apparatus of claim 20, the at least one processor further configured to:
receive at least one subsequent repetition of the code block after receiving the first number of repetitions of the code block; and
discard the at least one repetition of the code block.

23. The apparatus of claim 20, wherein the code block corresponds to an entire a transport block.

24. The apparatus of claim 20, wherein the code block corresponds to a portion of a transport block, and the transport block comprises a plurality of code blocks.

25. The apparatus of claim 20, wherein the code block is a first code block, the first code block corresponds to a first portion of a transport block, and the transport block comprises a plurality of code blocks, the at least one processor further configured to:
receive a second number of repetitions of a second code block at the UE, and the second code block corresponds to a second portion of the transport block; and
decode the second code block using the second number of repetitions.

26. The apparatus of claim 25, wherein the first number of repetitions is equal to the second number of repetitions.

27. The apparatus of claim 25, wherein the first number is not equal to the second number and the second number is less than the number of transmissions.

28. The apparatus of claim 25, wherein the second number is equal to the number of transmissions.

29. A computer program product stored on a computer-readable medium and comprising code that when executed on at least one processor causes the at least one processor to:
receive configuration information indicating a number of transmissions, the number of transmissions corresponding to a number of repetitions of a code block that will be transmitted by a base station;
receive a first number of repetitions of the code block at the UE, the first number being less than the number of transmissions; and
decode the code block using the first number of repetitions.

30. The computer program product of claim 29, further comprising code that when executed on the at least one processor causes the at least one processor to:
receive at least one subsequent repetition of the code block after receiving the first number of repetitions of the code block; and
discard the at least one repetition of the code block.
